(19) United States
(12) Patent Application Publication
(10) Pub. No.: US 2007/0054490 A1
(43) Pub. Date: Mar. 8, 2007

(54) Semiconductor process for preventing layer peeling in wafer edge area and method for manufacturing interconnects

(76) Inventors: Yen-Hung Chen, Hsinchu City (TW); Wen-Ping Yen, Hsinchu City (TW); Su-Ling Tseng, Hsinchu County (TW)

Correspondence Address: J C PATENTS, INC., 4 VENTURE, SUITE 250, IRVINE, CA, 92618, US

(21) Appl. No.: 11/218,457

(22) Filed: Sep. 2, 2005

(51) Int. Cl. H01L 21/302; H01L 21/31

(52) U.S. Cl. 438/689; 438/745; 438/780; 438/782

(57) ABSTRACT

A semiconductor process for preventing the layer on a wafer edge from peeling is provided. First, a dielectric layer is formed on the front side of a substrate. Then, a photoresist layer is formed to cover the front side and part of the backside of the substrate. Thereafter, an edge rinsing process is carried out only on the backside of the substrate to remove the photoresist layer on the back of the substrate while retaining the photoresist layer on the wafer edge area.

### BACKGROUND OF THE INVENTION

1. Field of the Invention

The present invention relates to a semiconductor fabrication process. More particularly, the present invention relates to a semiconductor process for preventing layer peeling in wafer edge area and manufacturing interconnects.

2. Description of the Related Art

In general, the fabrication of integrated circuits on a substrate involves forming a plurality of multi-layered stacked structures using various techniques. Each layer in the multi-layered stacked structures provide a particular function such as serving as a conductive layer, a dielectric layer, an insulating layer or an adhesion layer for increasing the adhesive strength between two adjacent layers. Frequently, each layer is fabricated using a different type of material to enhance the performance of the devices.

For example, in the conventional method of fabricating integrated circuits, after depositing dielectric material over a substrate to form a dielectric layer, a photoresist layer is formed over the dielectric layer. Then, the front and the back of the wafer will be rinsed to remove the photoresist layer in the wafer edge area. Thereafter, the dielectric layer is patterned. After that, other film layers are formed on the dielectric layer or other subsequent processes are performed.

However, with the photoresist layer on the front side of the wafer edge area of the substrate already removed, the dielectric layer on the wafer edge area will also be removed to expose the wafer after the etching operation. When other processes are subsequently carried out on the substrate in the wafer edge area, defects are easily formed and organic impurities from the subsequent processes are easily deposited on the surface. If a film layer is subsequently formed on the substrate, the organic impurities in the wafer edge area may form air bubbles when heated. Ultimately, the film layer may peel off leading to product damages and erratic machine operations. As a result, the entire batch of substrates may be damaged, leading to a significant drop in the product yield of the devices.

### SUMMARY OF THE INVENTION

Accordingly, at least one objective of the present invention is to provide a semiconductor process for preventing layer peeling in the wafer edge area of a substrate so that the surface of the substrate in the wafer edge area is protected against possible damages.

At least a second objective of the present invention is to provide a semiconductor process capable of retaining a dielectric layer on the wafer edge area of a substrate to prevent a direct exposure of the substrate.

At least a third objective of the present invention is to provide a method for fabricating interconnects capable of preventing the peeling of layers at the wafer edge area of a substrate so that a high product yield can be maintained.

To achieve these and other advantages and in accordance with the purpose of the invention, as embodied and broadly described herein, the invention provides a semiconductor process for preventing the peeling of layers in the wafer edge area. First, a substrate having a front side and a backside is provided. The front side includes the upper surface and the upper half of the side edge of the substrate and the backside includes the lower surface and the lower half of the side edge of the substrate. Furthermore, the upper surface has a wafer edge area and a central area. The wafer edge area surrounds the outer edge of the upper surface. Then, a dielectric layer is formed on the front side of the substrate. Thereafter, a photoresist layer is formed to cover the front side of the substrate, the lower half of the side edge and a portion of the lower surface. After that, only the backside of the substrate is rinsed to remove the photoresist layer on the backside of the substrate while retaining the photoresist layer on the wafer edge area.

According to the semiconductor process for preventing the peeling of layers in the wafer edge area in the embodiment of the present invention, the wafer edge area has a width of about 5 mm, for example.

According to the semiconductor process for preventing the peeling of layers in the wafer edge area in the embodiment of the present invention, the process of forming the dielectric layer includes performing a high-density plasma chemical vapor deposition (HDPCVD).

According to the semiconductor process for preventing the peeling of layers in the wafer edge area in the embodiment of the present invention, the dielectric layer is fabricated using silicon oxide, for example.

According to the semiconductor process for preventing the peeling of layers in the wafer edge area in the embodiment of the present invention, the step of rinsing the backside of the substrate includes performing an edge bead rinsing (EBR) operation.

According to the semiconductor process for preventing the peeling of layers in the wafer edge area in the embodiment of the present invention, the step of forming the photoresist layer includes performing a spin-coating process, for example.

The present invention also provides an alternative semiconductor fabrication process capable of preventing the peeling of layers in the wafer edge area. First, a dielectric layer is formed on the front side of a substrate. Then, the dielectric layer in the wafer edge area of the substrate is retained after the dielectric layer is patterned.

According to the semiconductor process for preventing the peeling of layers in the wafer edge area in the embodiment of the present invention, the step of retaining the dielectric layer on the wafer edge area of the substrate includes forming a photoresist layer to cover the front side of the substrate, the lower half of the side and part of the lower surface. Then, only the backside of the substrate is edge-rinsed so that the photoresist layer on the backside of the substrate is removed. Thereafter, the dielectric layer located within the central region of the substrate is patterned and the dielectric layer in the wafer edge area of the substrate is retained.

The present invention also provides a method for fabricating interconnects. First, a dielectric layer is formed on the front side of a substrate. Then, a photoresist layer is formed over the substrate to cover the front side, lower half side and part of the lower surface. Thereafter, only the lower surface and the lower half side of the substrate are edge-rinsed to remove the photoresist layer on the backside of the substrate. After that, the photoresist layer is patterned and an etching operation is carried out to pattern the dielectric layer in the front central area of the substrate so that the dielectric layer in the wafer edge area of the substrate is retained. Then, a patterned conductive layer is formed over the dielectric layer.

In the edge rinsing operation of the present invention, only the backside of the substrate is rinsed using an edge bead rinsing (EBR) method to remove the photoresist layer on the backside of the substrate. In other words, the wafer edge area in the front side of the substrate is not edge-rinsed. With the dielectric layer retained on the substrate in the wafer edge region and the substrate is covered in a subsequent operation, possible damages to the substrate in this area in the subsequent operation resulting in the deposition of organic impurities on the top surface of the substrate is prevented. Ultimately, the peeling of film layers (such as metallic layers) close to the wafer edge area is avoided so that a higher product yield is obtained.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a flow diagram showing the steps in a semiconductor fabrication method for preventing the peeling of layers in the wafer edge area according to one embodiment of the present invention.

FIG. 1B is a top view of a wafer.

FIGS. 2A through 2C are schematic cross-sectional views showing the steps for fabricating interconnects according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

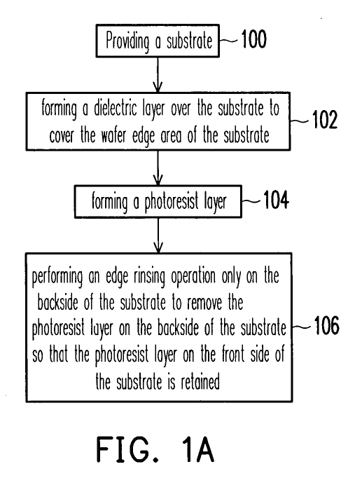

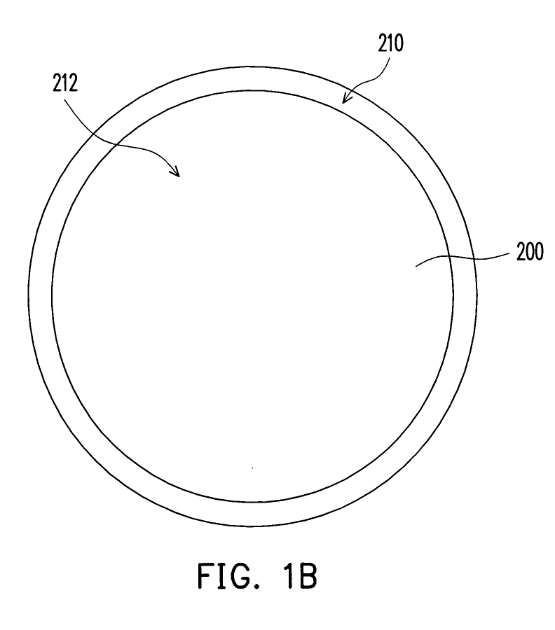

FIG. 1A is a flow diagram showing the steps in a semiconductor fabrication method for preventing the peeling of layers in the wafer edge area according to one embodiment of the present invention. In step 100 as shown in FIG. 1A, a substrate having a front side and a backside is provided. The front side of the substrate includes the upper surface and the upper half side of the substrate. The backside of the substrate includes the lower surface and the lower half side of the substrate. In addition, the upper surface of the substrate has a wafer edge area. The wafer edge area surrounds the outer edge of the upper surface of the substrate. The wafer edge area has a width of about 5 mm, for example. Then, in step 102, a dielectric layer is formed over the front side of the substrate, which covers the wafer edge area. The dielectric layer is fabricated using silicon oxide and formed by performing a high-density plasma chemical vapor deposition (HDPCVD) process, for example. Thereafter, in step 104, a photoresist layer is formed over the substrate by performing a spin-coating operation, for example. The photoresist layer covers the front side, the lower half side and part of the lower surface of the substrate. After that, in step 106, only the backside of the substrate is edge-rinsed to remove the photoresist layer on the backside of the substrate. The edge rinsing process is an edge bead rinsing operation, for example. In the rinsing step, the photoresist layer on the front side of the substrate is not rinsed so that the photoresist layer on the wafer edge area is retained. Therefore, the dielectric layer on the wafer edge area will not be removed to expose the substrate when the dielectric layer is patterned in an etching operation. In other words, byproducts such as organic impurities formed in a subsequent operation are prevented from depositing on the substrate, which may leading to the peeling of subsequently formed film layers on the wafer edge area.

In the following, the semiconductor process for preventing the peeling of film layers in the wafer edge area is explained using an interconnect structure as an example.

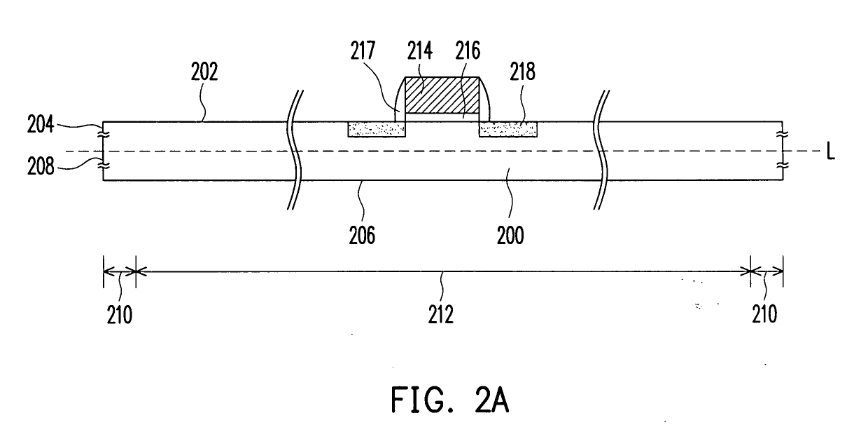

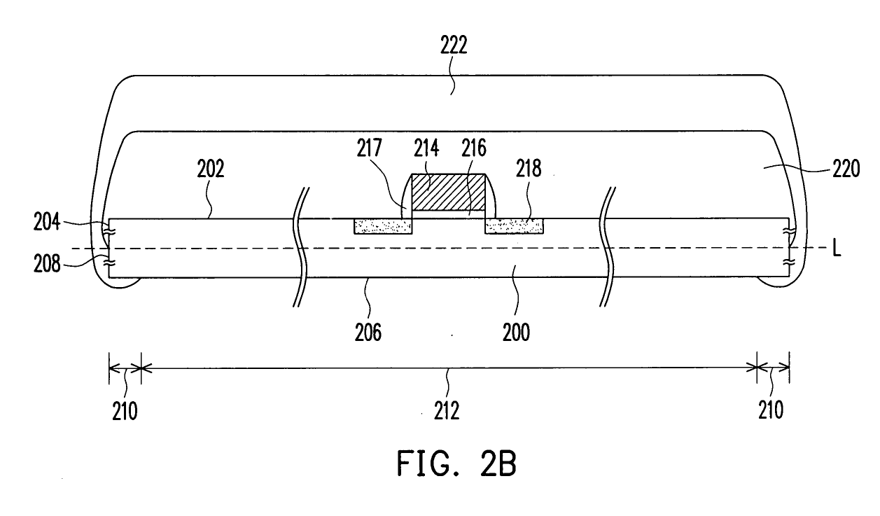

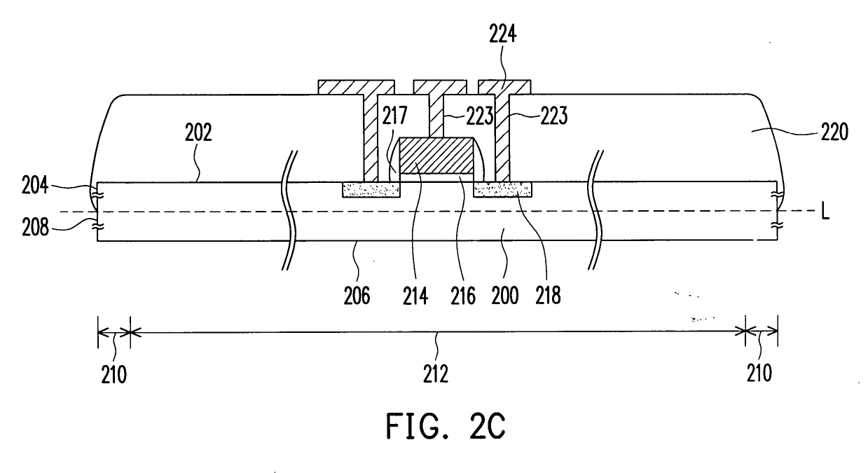

FIG. 1B is a top view of a wafer. FIGS. 2A through 2C are schematic cross-sectional views showing the steps for fabricating interconnects according to one embodiment of the present invention. As shown in FIG. 2A, a substrate 200 is provided. A central line L divides the substrate 200 into a front side and a backside. The front side includes the upper surface 202 and the upper half side 204 of the substrate 200. The backside includes the lower surface 206 and the lower half side 208 of the substrate 200. Furthermore, the upper surface 202 has a wafer edge area 210 and a central area 212. The wafer edge area 210 surrounds the outer edge of the substrate 200 (as shown in FIG. 1B) and has a width of about 5 mm, for example. The central area 212 has semiconductor devices formed thereon. Each semiconductor devices includes, for example, a gate 214, a gate dielectric layer 216, spacers 217 and source/drain regions 218. Obviously, the semiconductor devices can be some other devices as well.

As shown in FIG. 2B, a dielectric layer 220 is formed on the front side of the substrate 200. The dielectric layer 220 is fabricated using silicon oxide and formed, for example, by performing a high-density plasma chemical vapor deposition (HDPCVD) process. Alternatively, the dielectric layer 220 can be a composite layer comprising a silicon oxide layer and silicon nitride layer or silicon oxy-nitride or the other material layer. Then, a photoresist layer 222 is formed over the substrate 200. The photoresist layer 222 is formed, for example, by performing a spin-coating process. Besides covering the upper surface 202 of the substrate 200, the photoresist layer 222 is also attached to the upper half side 204, the lower half side 208 and even part of the lower surface 206.

As shown in FIG. 2C, an edge rinsing operation of the substrate 200 is carried out. The present embodiment differs from the conventional edge rinsing process in that only the backside (the lower half side 208 and the lower surface 206) of the substrate 200 is rinsed using, for example, an edge bead rinsing operation. Thus, the photoresist layer 222 on the backside of the substrate 200 is removed. Without edge rinsing the front side of the substrate 200, the photoresist layer 222 on the wafer edge area 210 is retained. Thereafter, the photoresist layer 222 is patterned. It should be noted that the photoresist layer 222 is retained on the wafer edge area 210 after the rinsing step. Then, an etching operation is carried out to form an opening 223 in the dielectric layer 220. Because there is no edge rinsing of the photoresist layer 222 in the wafer edge area and no operation to remove the photoresist layer 222 on the wafer edge in the photoresist patterning process, the dielectric layer 220 still covers up the wafer edge area 210. Hence, the substrate 200 is prevented from bare exposure. Thereafter, a conductive layer (not shown) is formed over the dielectric layer 220. The conductive material layer is a metallic layer, for example. Finally, the conductive material layer is patterned to form a conductive layer 224 that serves as a contact plug and a wire line.

In summary, in the edge rinsing process of the present invention, only the backside of the substrate is rinsed using an edge bead rinsing (EBR) method to remove the photoresist layer on the backside of the substrate. In other words, the wafer edge area in the front side of the substrate is not edge-rinsed so that the photoresist layer is retained. Furthermore, the photoresist layer in the wafer edge area is still retained in the process of patterning the photoresist layer. Therefore, the dielectric layer still covers the wafer edge area in a subsequent operation, thereby preventing any possible damages to the substrate due to exposure and the possible deposition of byproduct such as organic impurities formed in the subsequent operation on the top surface of the substrate. Ultimately, the peeling of film layers (such as metallic layers) close to the wafer edge area is avoided so that a higher product yield is obtained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor process for preventing layers in a wafer edge area from peeling, comprising the steps of:
providing a substrate having a front side and a backside, wherein the front side includes an upper surface and an upper half side of the substrate and the backside includes a lower surface and a lower half side of the substrate, and furthermore, the upper surface has a wafer edge area and a central : area and the wafer edge area surrounds the outer edge of the upper surface;
forming a dielectric layer over the front side of the substrate;
forming a photoresist layer to cover the front surface, the lower half side and part of the lower surface of the substrate; and
performing an edge rinsing operation only on the backside of the substrate to remove the photoresist layer on the backside of the substrate and retain the photoresist layer on the wafer edge area.

2. The semiconductor process of claim 1, wherein the wafer edge area has a width of about 5 mm.

3. The semiconductor process of claim 1, wherein the material constituting the dielectric layer comprises silicon oxide.

4. The semiconductor process of claim 1, wherein the step of forming the dielectric layer includes performing a high-density plasma chemical vapor deposition (HDPCVD) process.

5. The semiconductor process of claim l, wherein the step of performing an edge rinsing operation includes performing an edge bead rinsing (EBR) process.

6. The semiconductor process of claim 1, wherein the step of forming the photoresist layer includes performing a spin-coating process.

7. A semiconductor process for preventing layers in a wafer edge area from peeling, comprising the steps of:
providing a substrate having a front side and a backside, wherein the front side includes an upper surface and an upper half side of the substrate and the backside includes a lower surface and a lower half side of the substrate, and furthermore, the upper surface has a wafer edge area and a central area and the wafer edge area surrounds the outer edge of the upper surface;
forming a dielectric layer over the front side of the substrate; and
patterning the dielectric layer but retaining the dielectric layer in the wafer edge area in the process of patterning the dielectric layer.

8. The semiconductor process of claim 7, wherein the method of retaining the dielectric layer in the wafer edge area includes:
forming a photoresist layer to cover the front side, the lower half side and part of the lower surface of the substrate,
performing an edge rinsing operation only on the backside of the substrate to remove the photoresist layer on the backside of the substrate; and
patterning the dielectric layer in the central area.

9. The semiconductor process of claim 8, wherein the edge rinsing operation includes performing an edge bead rinsing (EBR) process.

10. A method for fabricating interconnects, comprising the steps of:
providing a substrate having a front side and a backside, wherein the front side includes an upper surface and an upper half side of the substrate and the backside includes a lower surface and a lower half side of the substrate, and furthermore, the upper surface has a wafer edge area and a central area and the wafer edge area surrounds the outer edge of the upper surface;
forming a dielectric layer over the front side of the substrate;
forming a photoresist layer over the substrate to cover the front side, the lower half side and part of the lower surface of the substrate:
performing an edge rinsing operation only on the backside of the substrate to remove the photoresist layer on the backside of the substrate;
patterning the photoresist layer in the central area but retaining the photoresist layer in the wafer edge area;
patterning the dielectric layer using the photoresist layer as a mask; and
forming a patterned conductive layer over the dielectric layer.

11. The method of claim 10, wherein the wafer edge area has a width of about 5 mm.

12. The method of claim 10, wherein the material constituting the dielectric layer comprises silicon oxide.

13. The method of claim 12, wherein the step of forming the dielectric layer includes performing a high-density plasma chemical vapor deposition (HDPCVD) process.

14. The method of claim 10, wherein the step of performing an edge rinsing operation includes performing an edge bead rinsing (EBR) process.

15. The method of claim 10, wherein the step of forming the photoresist layer includes performing a spin-coating process.
